(19) United States
(12) Patent Application Publication
(10) Pub. No.: US 2026/0114041 A1
(43) Pub. Date: Apr. 23, 2026

(54) METAL GATE STRUCTURES WITH AIRGAPS AND METHODS FOR PREPARING THE SAME

(71) Applicant: Applied Materials, Inc., Santa Clara, CA (US)

(72) Inventors: Sai Hooi YEONG, Cupertino, CA (US); Zeqing SHEN, San Jose, CA (US); Ashish PAL, San Ramon, CA (US); El Mehdi BAZIZI, San Anselmo, CA (US); Abhijit Basu MALLICK, Fremont, CA (US); Benjamin COLOMBEAU, San Jose, CA (US); Balasubramanian PRANATHARTHIHARAN, Santa Clara, CA (US)

(21) Appl. No.: 19/323,991

(22) Filed: Sep. 9, 2025

Related U.S. Application Data
(60) Provisional application No. 63/710,008, filed on Oct. 21, 2024.

(51) Int. Cl. H10D 84/85; H01L 21/02; H01L 21/762; H01L 21/764; H10D 30/00; H10D 30/01; H10D 62/13; H10D 84/01

(52) U.S. Cl. CPC H10D 84/851; H10D 30/019; H10D 30/502; H10D 62/151; H10D 84/0188; H10P 14/6339; H10P 14/6902; H10P 14/69215; H10P 14/6927; H10W 10/0145; H10W 10/021; H10W 10/17; H10W 10/20

(57) ABSTRACT

Embodiments of the present disclosure generally relate to metal gate devices. In one or more embodiments, a method for preparing a device with an airgap is provided and includes depositing a silicon-containing layer on inner surfaces of trenches formed in a metal-gate layer disposed on a substrate, depositing a carbon-containing layer on the silicon-containing layer in the trenches, the carbon-containing layer is deposited to fill at least a lower half of the trenches from the bottom, and leaving a temporary gap within each trench at the top. The method also includes depositing a low-k dielectric layer on the carbon-containing layer and the silicon-containing layer to fill the temporary gap, and exposing at least the carbon-containing layer to a treatment process to remove the carbon-containing layer and form the airgap between the silicon-containing layer and the low-k dielectric layer.

### CROSS-REFERENCE TO RELATED APPLICATIONS

This application claims benefit of U.S. Appl. No. 63/710,008, filed on Oct. 21, 2024, which is herein incorporated by reference in its entirety.

### BACKGROUND

### Field

Embodiments of the present disclosure generally relate to metal gate devices, and more specifically, methods for fabricating metal gate structures containing airgaps.

### Description of the Related Art

Complementary metal-oxide-semiconductor (CMOS) is a type of metal-oxide-semiconductor field-effect transistor (MOSFET) fabrication process that uses complementary and symmetrical pairs of p-type and n-type MOSFETs for logic functions. CMOS technology is used for constructing integrated circuit (IC) chips, including microprocessors, microcontrollers, memory chips (including CMOS BIOS), and other digital logic circuits. CMOS technology is also used for analog circuits such as image sensors (CMOS sensors), data converters, RF circuits (RF CMOS), and highly integrated transceivers for many types of communication.

During the fabrication process, trenches and other cuts are formed in the metal oxide gate layer. Typically, the metal gate cuts are filled with one or more dielectric materials containing silicon, such as silicon nitride, silicon oxide, or both. However, the CMOS device often suffers from front end of line (FEOL) parasitic capacitance which reduces the overall speed of the device.

Therefore, a need exists for new metal gate devices and methods for fabricating the same.

### BRIEF DESCRIPTION OF THE DRAWINGS

So that the manner in which the above recited features of the present disclosure may be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a flowchart depicting a method for preparing an airgap, according to one or more embodiments described and discussed herein.

FIGS. 2A-2D depict a workpiece at different fabrication processes while following the method depicted in FIG. 1, according to one or more embodiments described and discussed herein.

FIG. 3 is a flowchart depicting another method for preparing an airgap, according to one or more embodiments described and discussed herein.

FIGS. 4A-4F depict a workpiece at different fabrication processes while following the method depicted in FIG. 3, according to one or more embodiments described and discussed herein.

FIGS. 5A-5B depict cross-sectional views of a device containing the airgap depicted in FIG. 2D, according to one or more embodiments described and discussed herein.

FIGS. 6A-6B depict cross-sectional views of a device containing the airgap depicted in FIG. 4F, according to one or more embodiments described and discussed herein.

To facilitate understanding, identical reference numerals have been used, where possible, to designate identical elements that are common to the Figures. It is contemplated that elements and features of one or more embodiments may be beneficially incorporated in other embodiments.

### SUMMARY

Embodiments of the present disclosure generally relate to metal gate devices, and more specifically, methods for fabricating metal gate structures containing airgaps. The metal gate devices with an airgap may be or include one or more transistors, such as a complementary metal-oxide-semiconductor (CMOS) transistor, a metal-oxide-semiconductor field-effect transistor (MOSFET), a gate-all-around (GAA) transistor, a fin field effect transistor (FinFET), complementary field effect transistor (CFET), or other types of transistors.

In one or more embodiments, a method for preparing a device with an airgap is provided and includes depositing a silicon-containing layer (e.g., silicon nitride) on inner surfaces of trenches formed in a metal-gate layer disposed on a substrate, wherein each of the trenches has a top and a bottom, depositing a carbon-containing layer (e.g., amorphous carbon) on the silicon-containing layer in the trenches during a bottom-up deposition process, where the carbon-containing layer is deposited to fill at least a lower half of the trenches from the bottom, and ceasing or otherwise stopping the bottom-up deposition process to leave a temporary gap within each trench at the top. The method also includes depositing a low-k dielectric layer into the temporary gap (and in some examples, depositing the low-k dielectric layer on the carbon-containing layer and the silicon-containing layer to completely fill or substantially fill the temporary gap), and exposing at least the carbon-containing layer to a treatment process to remove the carbon-containing layer and form the airgap between the silicon-containing layer and the low-k dielectric layer.

In other embodiments, a method for preparing a device with an airgap is provided and includes depositing a silicon-containing layer (e.g., silicon nitride) on inner surfaces of trenches formed in a metal-gate layer disposed on a substrate, wherein the inner surfaces of trenches for each of the trenches contain sidewalls and a bottom, depositing a carbon-containing layer (e.g., amorphous carbon) on the silicon-containing layer which is disposed on the sidewalls and the bottoms of the trenches during a first deposition process, and ceasing or otherwise stopping the first deposition process to leave a temporary gap within each trench. The method also includes removing the carbon-containing layer from the bottom of each temporary gap while exposing the silicon-containing layer at the bottom of each temporary gap, and depositing an oxide layer into each temporary gap during a second deposition process to fill the temporary gap. The method further includes exposing the carbon-containing layer to a treatment process to remove the carbon-containing layer and form dielectric airgaps between the silicon-containing layer and the oxide layer, and depositing a capping layer over the airgaps, the silicon-containing layer, and the oxide layer.

In one or more embodiments, a device is provided and contains a metal-gate layer disposed on or over a substrate, trenches formed within the metal-gate layer, a silicon-containing layer (e.g., silicon nitride) disposed on inner surfaces of the trenches, and a low-k dielectric layer disposed over the silicon-containing layer and at least partially within each of the trenches, where the airgap is disposed between and/or encapsulated by the silicon-containing layer and the low-k dielectric layer in each of the trenches.

In other embodiments, a device is provided and contains a metal-gate layer disposed on or over a substrate, trenches formed within the metal-gate layer, a silicon-containing layer (e.g., silicon nitride) disposed on inner surfaces of the trenches, an oxide layer extending from the silicon-containing layer at the bottom of each trench, and a capping layer disposed on the silicon-containing layer and the oxide layer at a top of each trench, where dielectric airgaps are disposed between and/or encapsulated by the silicon-containing layer, the oxide layer, and the capping layer.

### DETAILED DESCRIPTION

Embodiments of the present disclosure generally relate to metal gate devices, and more specifically, methods for fabricating metal gate structures containing airgaps (e.g., dielectric gaps). The metal gate devices with airgaps may be or include one or more transistors, such as a complementary metal-oxide-semiconductor (CMOS) transistor, a metal-oxide-semiconductor field-effect transistor (MOSFET), a gate-all-around (GAA) transistor, a fin field effect transistor (FinFET), complementary field effect transistor (CFET), or other types of transistors.

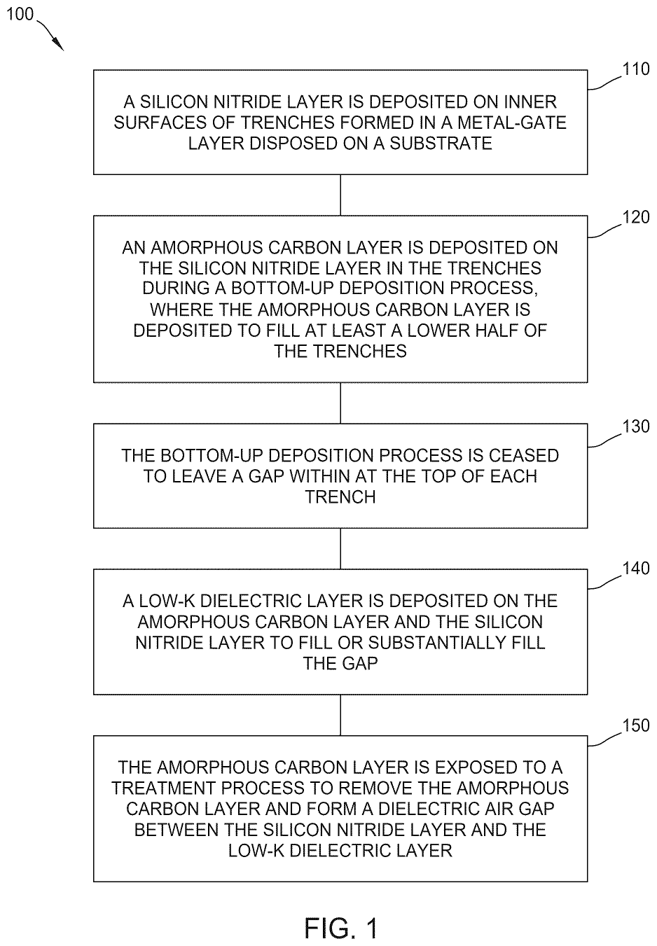

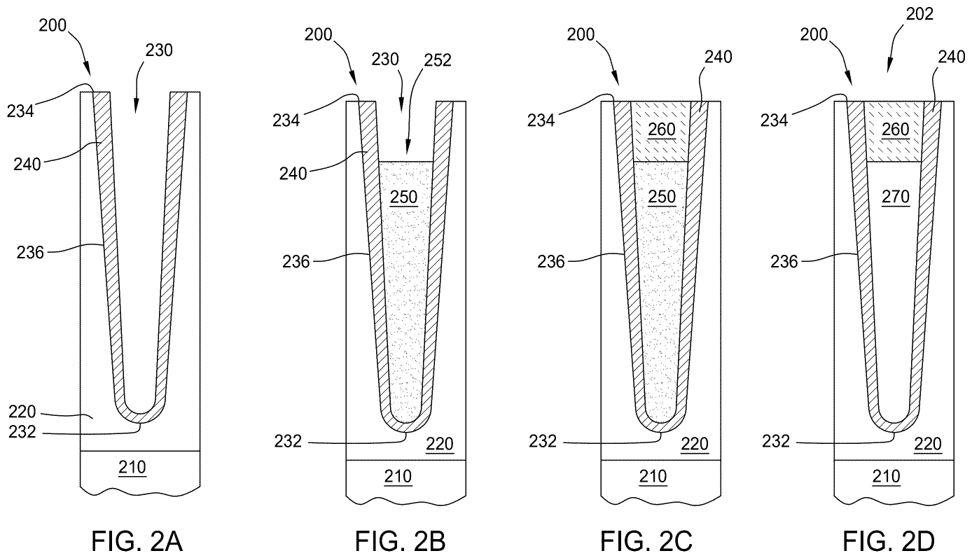

FIG. 1 is a flowchart depicting a process or method 100 for preparing gate cut airgaps for metal gate devices, according to one or more embodiments described and discussed herein. The method 100 includes operations 110-150, as further discussed below. FIGS. 2A-2D depict a workpiece 200 at different fabrication processes, such as operations 110-150, while following the method 100, according to one or more embodiments described and discussed herein.

In one or more embodiments, a method for preparing gate cut airgaps on the workpiece 200 is provided and includes depositing a silicon-containing layer 240 on inner surfaces of trenches 230 formed in a metal-gate layer 220 disposed on a substrate 210 (operation 110). Each of the trenches 230 may have a bottom 232, a top 234, and sidewalls 236 therebetween. The method 100 also includes depositing a carbon-containing layer 250 on the silicon-containing layer 240 in the trenches 230 during a bottom-up deposition process (operation 120). The carbon-containing layer 250 may be deposited to fill at least a lower half of the trenches 230 from the bottom 232. The method 100 also includes ceasing or otherwise stopping the bottom-up deposition process to leave a temporary gap 252 within each trench 230 at the top 234 (operation 130). The method 100 further includes depositing a low-k dielectric layer 260 into the temporary gap 252 (operation 140). In one or more examples, the low-k dielectric layer 260 may be deposited on the carbon-containing layer 250 and the silicon-containing layer 240 to completely fill or substantially fill the temporary gap 252 at operation 140. The method 100 also includes exposing at least the carbon-containing layer 250 to a treatment process to remove the carbon-containing layer 250 and form the dielectric gap or airgap 270 between the silicon-containing layer 240 and the low-k dielectric layer 260 while producing, fabricating, or otherwise forming a device 202 (operation 150). The airgaps 270 described and discussed here are dielectric gaps due to the dielectric properties of air.

After operation 150, the workpiece 200, as depicted in FIG. 2D, contains the device 202 on substrate 210. In one or more embodiments, the device 202 contains the metal-gate layer 220 disposed on or over the substrate 210, trenches 230 formed within the metal-gate layer 220, the silicon-containing layer 240 disposed on inner surfaces of the trenches 230, and the low-k dielectric layer 260 disposed over the silicon-containing layer 240 and at least partially within each of the trenches 230. Also, the airgaps 270 are disposed between and/or encapsulated by the silicon-containing layer 240 and the low-k dielectric layer 260 in each of the trenches 230.

A plurality of devices 202 may be produced, fabricated, manufactured, or otherwise made by the method 100. In other embodiments, other devices, not described or discussed herein, may also be produced, fabricated, manufactured, or otherwise made by the method 100. In one or more examples, the device 202 is, comprises, includes, consists of, or consists essentially of, one or more transistors. In some examples, the device 202 (or the transistor) is a complementary metal-oxide-semiconductor (CMOS) transistor, a metal-oxide-semiconductor field-effect transistor (MOSFET), a gate-all-around (GAA) transistor, a fin field effect transistor (FinFET), complementary field effect transistor (CFET), other types of transistors, or any combination thereof.

Although FIG. 2D depicts a single device 202 with the airgap 270 on the workpiece 200, in practice, numerous amounts (e.g., up to millions) of the devices 202 with the airgaps 270 may be produced, fabricated, manufactured, or otherwise made on the workpiece 200 by the method 100. In addition, although FIGS. 2A-2D depict the metal-gate layer 220 deposited or disposed directly on or over the substrate 210, in practice one or more other layers and/or materials may be between the metal-gate layer 220 and the substrate 210 depending on the specific architecture of the overall microelectronic device.

Prior to operation 110, the workpiece 200 containing the metal-gate layer 220 disposed on the substrate 210 may be exposed to one or more processes or operations in order to form the trenches 230. For example, the trenches 230 may be produced, fabricated, or otherwise formed in the metal-gate layer 220 by one or more etching process, such as one or more wet etch processes, one or more dry etch processes, of any combination thereof.

In one or more embodiments, each of the trenches 230 may have an aspect ratio in a range from about 4, about 5, about 6, about 7, about 8, about 9, about 10, about 12, or about 14 to about 15, about 16, about 18, about 20, about 22, about 25, about 28, about 30, about 35, about 40, about 45, about 50, about 60, about 75, about 80, about 100, or greater. For example, each of the trenches 230 may have an aspect ratio in a range from about 4 to about 100, about 6 to about 100, about 6 to about 80, about 6 to about 50, about 6 to about 40, about 6 to about 30, about 6 to about 20, about 6 to about 15, about 6 to about 12, about 6 to about 10, about 6 to about 8, about 8 to about 100, about 8 to about 80, about 8 to about 50, about 8 to about 40, about 8 to about 30, about 8 to about 20, about 8 to about 15, about 8 to about 12, about 8 to about 10, about 10 to about 100, about 10 to about 80, about 10 to about 50, about 10 to about 40, about 10 to about 30, about 10 to about 20, about 10 to about 15, or about 10 to about 12. The aspect ratio is measured as a ratio of depth (or height) over width (or diameter) of the trench 230.

At operation 110, the silicon-containing layer 240 deposited, disposed, or otherwise formed on inner surfaces of trenches 230 formed in the metal-gate layer 220 which is disposed on or above the substrate 210. Each of the trenches 230 may have a bottom 232, a top 234, and sidewalls 236 therebetween. In some examples, the top 234 of each trench 230 may have a width or a diameter greater than the bottom 232 of each trench 230 (as depicted in FIGS. 2A-2D). In other examples, not shown, the top 234 of each trench 230 may have a width or a diameter equal to or substantially equal to the bottom 232 of each trench 230, such the sidewalls 236 are parallel or substantially parallel to each other.

The silicon-containing layer 240 may be or contain silicon nitride, silicon oxide, silicon oxynitride, or any combination thereof. In one or more examples, the silicon-containing layer 240 may be or contain silicon nitride. In some examples, the silicon-containing layer 240 consists completely of silicon nitride or consist essentially of silicon nitride. In other embodiments, the silicon-containing layer 240 may or contain one or more dielectric materials which can be selectively maintained without being removed or damaged when removing the carbon-containing layer 250 while exposing the silicon-containing layer 240 in a later fabrication process (e.g., operation 150). The silicon-containing layer 240 may be deposited or otherwise formed by one or more vapor deposition processes. Exemplary vapor deposition processes may be or include a thermal atomic layer deposition (ALD) process, a plasma-enhanced ALD (PE-ALD) process, a thermal chemical vapor deposition (CVD) process, a plasma-enhanced CVD (PE-CVD) process, a physical vapor deposition (PVD) process, or any combination thereof.

In one or more embodiments, the silicon-containing layer 240 may have a thickness in a range from about 0.1 nm, about 0.5 nm, about 0.8 nm, about 1 nm, about 1.5 nm, about 2 nm, about 3 nm, or about 4 nm to about 5 nm, about 6 nm, about 7 nm, about 8 nm, about 9 nm, about 10 nm, about 12 nm, about 15 nm, about 18 nm, about 20 nm, about 30 nm, about 50 nm, or greater. For example, the silicon-containing layer 240 may have a thickness in a range from about 0.1 nm to about 50 nm, about 0.5 nm to about 50 nm, about 1 nm to about 50 nm, about 2 nm to about 50 nm, about 3 nm to about 50 nm, about 4 nm to about 50 nm, about 5 nm to about 50 nm, about 8 nm to about 50 nm, about 10 nm to about 50 nm, about 15 nm to about 50 nm, about 20 nm to about 50 nm, about 0.5 nm to about 10 nm, about 1 nm to about 10 nm, about 2 nm to about 10 nm, about 3 nm to about 10 nm, about 4 nm to about 10 nm, about 5 nm to about 10 nm, about 8 nm to about 10 nm, about 0.5 nm to about 5 nm, about 1 nm to about 5 nm, about 2 nm to about 5 nm, about 3 nm to about 5 nm, about 4 nm to about 5 nm, about 0.5 nm to about 3 nm, about 1 nm to about 3 nm, or about 2 nm to about 3 nm.

At operation 120, the carbon-containing layer 250 may be deposited, disposed, or otherwise formed in the trenches 230 and on the silicon-containing layer 240 during a bottom-up deposition process. In one or more examples, the carbon-containing layer 250 comprises, contains, includes, consists, or consists essential of amorphous carbon. In some examples, the carbon-containing layer 250 consists essential of amorphous carbon. In other embodiments, the carbon-containing layer 250 may or contain one or more sacrificial materials which can be selectively removed from the underlying layer, such as the silicon-containing layer 240, without removing or damaging the underlying layer.

The carbon-containing layer 250 may be deposited or otherwise formed by one or more vapor deposition processes. Exemplary vapor deposition processes may be or include a molecular layer deposition (MLD) process, a thermal ALD process, a PE-ALD process, a thermal CVD process, a PE-CVD process, a flowable CVD (F-CVD) process, or any combination thereof. In one or more examples, the carbon-containing layer 250 is deposited by an MLD process during the bottom-up deposition process.

The carbon-containing layer 250 may have a density in a range from about 0 g/cm³, about 0.0001 g/cm³, about 0.001 g/cm³, about 0.01 g/cm³, about 0.1 g/cm³, about 0.2 g/cm³, about 0.3 g/cm³, about 0.4 g/cm³, about 0.5 g/cm³, about 0.6 g/cm³, about 0.7 g/cm³, about 0.8 g/cm³, about 0.9 g/cm³, or about 1 g/cm³ to about 1.1 g/cm³, about 1.2 g/cm³, about 1.3 g/cm³, about 1.4 g/cm³, about 1.5 g/cm³, about 1.6 g/cm³, about 1.7 g/cm³, about 1.8 g/cm³, about 1.9 g/cm³, about 2 g/cm³, or greater. For example, the carbon-containing layer 250 may have a density in a range from about 0.01 g/cm³ to about 2 g/cm³, about 0.1 g/cm³ to about 2 g/cm³, about 0.2 g/cm³ to about 2 g/cm³, about 0.5 g/cm³ to about 2 g/cm³, about 0.8 g/cm³ to about 2 g/cm³, about 1 g/cm³ to about 2 g/cm³, about 1.2 g/cm³ to about 2 g/cm³, about 1.5 g/cm³ to about 2 g/cm³, about 1.6 g/cm³ to about 2 g/cm³, about 1.8 g/cm³ to about 2 g/cm³, about 0.01 g/cm³ to about 1.5 g/cm³, about 0.1 g/cm³ to about 1.5 g/cm³, about 0.2 g/cm³ to about 1.5 g/cm³, about 0.5 g/cm³ to about 1.5 g/cm³, about 0.8 g/cm³ to about 1.5 g/cm³, about 1 g/cm³ to about 1.5 g/cm³, about 1.2 g/cm³ to about 1.5 g/cm³, about 1.3 g/cm³ to about 1.5 g/cm³, about 0.01 g/cm³ to about 1 g/cm³, about 0.1 g/cm³ to about 1 g/cm³, about 0.2 g/cm³ to about 1 g/cm³, about 0.5 g/cm³ to about 1 g/cm³, about 0.8 g/cm³ to about 1 g/cm³, about 0.9 g/cm³ to about 1 g/cm³, about 0.01 g/cm³ to about 0.8 g/cm³, about 0.1 g/cm³ to about 0.8 g/cm³, about 0.2 g/cm³ to about 0.8 g/cm³, about 0.5 g/cm³ to about 0.8 g/cm³, or about 0.6 g/cm³ to about 0.8 g/cm³.

At operation 130, the carbon-containing layer 250 may be deposited, disposed, or otherwise formed to fill at least a lower half of the trenches 230 from the bottom 232. The method 100 also includes ceasing or otherwise stopping the bottom-up deposition process to leave or otherwise produce a temporary gap 252 within each trench 230 at the top 234. The temporary gap 252 is a permanent fixture until the interior is later filled with one or more materials (e.g., the low-k dielectric layer 260).

The temporary gap 252 occupies less than an upper half of the trenches 230 at or near the top 234 at the conclusion of the bottom-up deposition process. The temporary gap 252 may occupy any depth of each trench 230. In some examples, the temporary gap 252 may occupy about 5% to about 25%, about 10% to about 25%, about 15% to about 25%, about 20% to about 25%, about 5% to about 20%, about 5% to about 15%, about 5% to about 10% of a depth of each trench 230.

At operation 140, the low-k dielectric layer 260 may be deposited, disposed, or otherwise formed into the temporary gap 252. In some examples, the low-k dielectric layer 260 may be deposited, disposed, or otherwise formed on the carbon-containing layer 250 and the silicon-containing layer 240 to completely fill or substantially fill the temporary gap 252 at operation 140. In one or more examples, the low-k dielectric layer 260 comprises, contains, includes, consists, or consists essential of silicon, carbon, and oxygen. The low-k dielectric layer 260 may be may be deposited, disposed, or otherwise formed by one or more deposition processes. Exemplary deposition processes may be or include an F-CVD process, a thermal ALD process, a PE-ALD process, a thermal CVD process, a PE-CVD process, or any combination thereof. In one or more examples, the low-k dielectric layer 260 is deposited by forming a flowable dielectric layer in the trenches 230, and then solidifying the low-k dielectric layer 260, such as by a thermal or annealing process, to produce the low-k dielectric layer 260. For example, the flowable dielectric layer may be formed during a vapor deposition process from one, two, or more silicon carbon precursors and one or more oxygen precursors (e.g., oxygenating agents). In one or more examples, the flowable dielectric layer may be formed during a vapor deposition process from a first silicon carbon precursor, a second silicon carbon precursor, and an oxygen precursor.

In one or more embodiments, the low-k dielectric layer 260 may have a thickness in a range from about 1 nm, about 5 nm, about 8 nm, about 10 nm, about 12 nm, about 15 nm, about 18 nm, or about 20 nm to about 25 nm, about 30 nm, about 35 nm, about 40 nm, about 45 nm, about 50 nm, about 60 nm, about 70 nm, about 80 nm, about 90 nm, about 100 nm, or greater. For example, the low-k dielectric layer 260 may have a thickness in a range from about 1 nm to about 100 nm, about 5 nm to about 100 nm, about 5 nm to about 80 nm, about 5 nm to about 60 nm, about 5 nm to about 50 nm, about 5 nm to about 40 nm, about 5 nm to about 30 nm, about 5 nm to about 25 nm, about 5 nm to about 20 nm, about 5 nm to about 15 nm, about 5 nm to about 10 nm, about 5 nm to about 8 nm, about 10 nm to about 100 nm, about 10 nm to about 80 nm, about 10 nm to about 60 nm, about 10 nm to about 50 nm, about 10 nm to about 40 nm, about 10 nm to about 30 nm, about 10 nm to about 25 nm, about 10 nm to about 20 nm, about 10 nm to about 15 nm, about 10 nm to about 12 nm, about 20 nm to about 100 nm, about 20 nm to about 80 nm, about 20 nm to about 60 nm, about 20 nm to about 50 nm, about 20 nm to about 40 nm, about 20 nm to about 30 nm, or about 20 nm to about 25 nm.

In some embodiments, the low-k dielectric layer 260 may have a dielectric constant in a range from about 1.5, about 1.6, about 1.7, about 1.8, about 1.9, about 2.0, about 2.1, about 2.2, about 2.3, about 2.4, or about 2.5 to about 2.6, about 2.7, about 2.8, about 2.9, about 3.0, about 3.1, about 3.2, about 3.3, about 3.4, about 3.5, about 3.6, about 3.7, about 3.8, about 3.9, about 4.0, about 4.2, about 4.5, about 4.8, or greater. For example, the low-k dielectric layer 260 has a dielectric constant in a range from about 1.5 to about 4.0, about 2.0 to about 4.0, about 2.2 to about 4.0, about 2.4 to about 4.0, about 2.6 to about 4.0, about 2.8 to about 4.0, about 3.0 to about 4.0, about 3.2 to about 4.0, about 3.4 to about 4.0, about 3.6 to about 4.0, about or greater than 2.0 to about 3.8, about or greater than 2.0 to about 3.6, about or greater than 2.0 to about 3.4, about or greater than 2.0 to about 3.2, about or greater than 2.0 to about 3.0, about or greater than 2.0 to about 2.8, about or greater than 2.0 to about 2.6, about or greater than 2.0 to about 2.4, about or greater than 2.0 to about 2.2, about or greater than 2.2 to about 3.8, about or greater than 2.2 to about 3.6, about or greater than 2.2 to about 3.4, about or greater than 2.2 to about 3.2, about or greater than 2.2 to about 3.0, about or greater than 2.2 to about 2.8, about or greater than 2.2 to about 2.6, about or greater than 2.2 to about 2.4, about or greater than 2.5 to about 3.8, about or greater than 2.5 to about 3.6, about or greater than 2.5 to about 3.4, about or greater than 2.5 to about 3.2, about or greater than 2.5 to about 3.0, about or greater than 2.5 to about 2.8, or about or greater than 2.5 to about 2.6.

At operation 150, the method 100 also includes exposing at least the carbon-containing layer 250 to a treatment process to remove, burn-off, oxidize, deteriorate, vaporize, or otherwise reduce the carbon-containing layer 250. In some examples, the carbon-containing layer 250, including the amorphous carbon therein, is converted into volatile species, such as carbon monoxide, carbon dioxide, or a combination thereof.

During the treatment process, the airgaps 270 are dielectric and formed or otherwise produced between the silicon-containing layer 240 and the low-k dielectric layer 260 while producing, fabricating, or otherwise forming the device 202. Each of the airgaps 270 is an airgap encapsulated by the silicon-containing layer 240 and the low-k dielectric layer 260.

In one or more embodiments, the carbon-containing layer 250 is exposed to ultraviolet (UV) radiation (e.g., UV light) during the treatment process. The UV radiation or light has a wavelength in a range from about 100 nm, about 120 nm, about 135 nm, about 150 nm, about 165 nm, about 180 nm, about 200 nm, about 220 nm, about 235 nm, about 250 nm, about 265 nm, about 280 nm, about 300 nm, or greater. For examples, the UV radiation or light has a wavelength in a range from about 100 nm to about 300 nm, about 150 nm to about 300 nm, about 150 nm to about 275 nm, about 150 nm to about 250 nm, about 150 nm to about 225 nm, about 150 nm to about 200 nm, about 150 nm to about 175 nm, about 180 nm to about 300 nm, about 180 nm to about 275 nm, about 180 nm to about 250 nm, about 180 nm to about 225 nm, about 180 nm to about 200 nm, about 200 nm to about 300 nm, about 200 nm to about 275 nm, about 200 nm to about 250 nm, or about 200 nm to about 225 nm.

In other embodiments, the carbon-containing layer 250 is heated to a temperature in a range from about 100° C., about 150° C., about 200° C., about 225° C., about 250° C., about 275° C., about 300° C., about 350° C., about 400° C., about 450° C., about 500° C., about 550° C., about 600° C., about 650° C., about 700° C., about 750° C., or greater during a thermal treatment. For example, the carbon-containing layer 250 is heated to a temperature in a range from about 150° C. to about 750° C., about 150° C. to about 700° C., about 150° C. to about 650° C., about 150° C. to about 600° C., about 150° C. to about 550° C., about 150° C. to about 500° C., about 150° C. to about 450° C., about 150° C. to about 400° C., about 150° C. to about 350° C., about 150° C. to about 300° C., about 150° C. to about 250° C., about 150° C. to about 200° C., about 250° C. to about 750° C., about 250° C. to about 700° C., about 250° C. to about 650° C., about 250° C. to about 600° C., about 250° C. to about 550° C., about 250° C. to about 500° C., about 250° C. to about 450° C., about 250° C. to about 400° C., about 250° C. to about 350° C., about 250° C. to about 300° C., about 350° C. to about 750° C., about 350° C. to about 700° C., about 350° C. to about 650° C., about 350° C. to about 600° C., about 350° C. to about 550° C., about 350° C. to about 500° C., about 350° C. to about 450° C., about 350° C. to about 400° C. during a thermal treatment.

After operation 150, one or more additional processes or operations may be performed on the workpiece 200. In one or more examples, the low-k dielectric layer 260 may be exposed to one or more polishing processes, such as a chemical mechanical polishing (CMP) process, to reduce a thickness of the low-k dielectric layer 260.

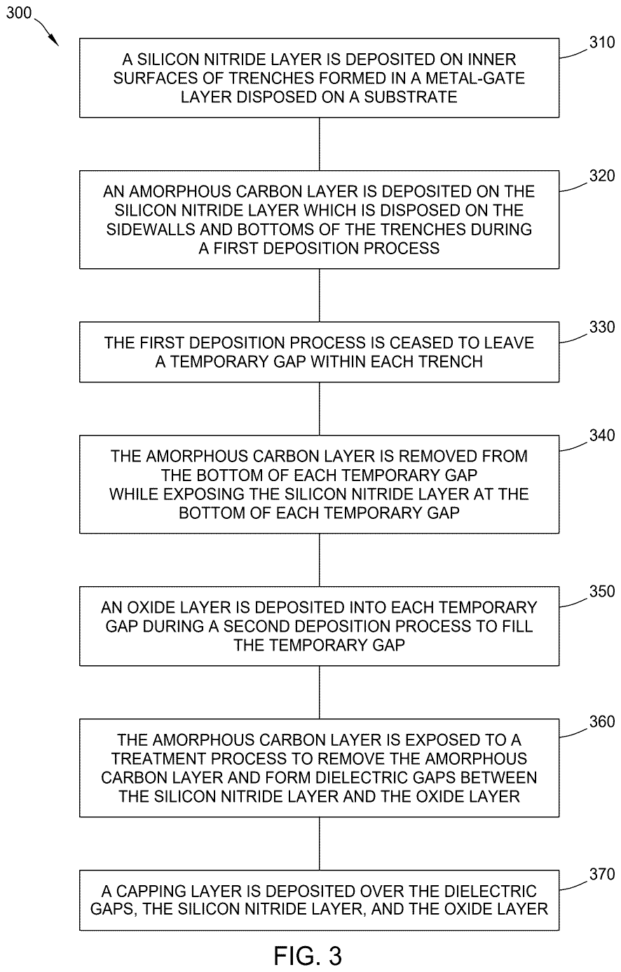

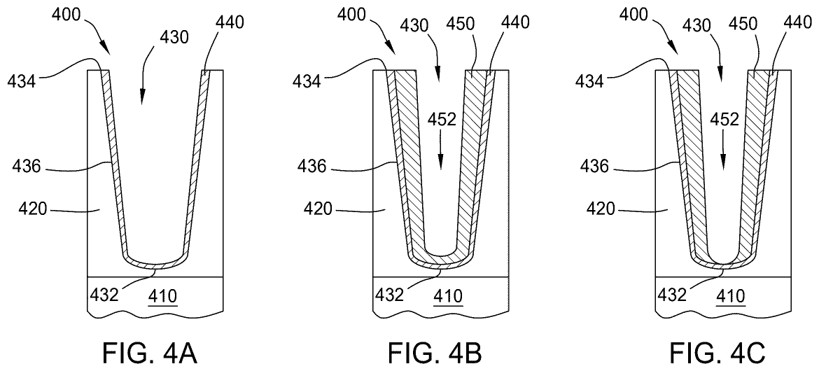

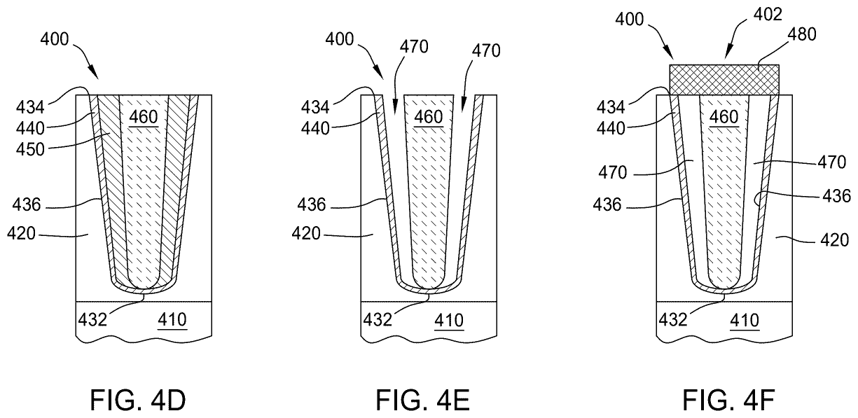

FIG. 3 is a flowchart depicting a process or method 300 for preparing an airgap for metal gate devices, according to one or more embodiments described and discussed herein. The method 300 includes operations 310-370, as further discussed below. FIGS. 4A-4F depict a workpiece 400 at different fabrication processes, such as operations 310-370, while following the method 300, according to one or more embodiments described and discussed herein.

In one or more embodiments, a method for preparing gate cut airgaps on the workpiece 400 is provided and includes depositing a silicon-containing layer 440 on inner surfaces of trenches 430 formed in a metal-gate layer 420 disposed on a substrate 410 (operation 310). The inner surfaces of trenches 430 for each of the trenches 430 contains a bottom 432, a top 434, and sidewalls 436 therebetween. The method 300 also includes depositing a carbon-containing layer 450 on the silicon-containing layer 440 which is disposed on the sidewalls 436 and the bottoms 432 of the trenches 430 during a first deposition process (operation 320). The method 300 further includes ceasing or otherwise stopping the first deposition process to leave a temporary gap 452 within each trench 430 (operation 330). The method further includes removing the carbon-containing layer 450 from the bottom 432 of each temporary gap 452 while exposing the silicon-containing layer 440 at the bottom 432 of each temporary gap 452 (operation 340). The method 300 also includes depositing an oxide layer 460 into each temporary gap 452 during a second deposition process to fill the temporary gap 452 (operation 350). The method also includes exposing the carbon-containing layer 450 to a treatment process to remove the carbon-containing layer 450 and form dielectric airgaps 470 between the silicon-containing layer 440 and the oxide layer 460 (operation 360). The method further includes depositing a capping layer 480 over the airgaps 470, the silicon-containing layer 440, and the oxide layer 460 while producing, fabricating, or otherwise forming a device 402 (operation 370).

After operation 370, the workpiece 400, as depicted in FIG. 4F, contains the device 402 on substrate 410. In one or more embodiments, the device 402 is provided and includes the metal-gate layer 420 disposed on or over the substrate 410, trenches 430 formed within the metal-gate layer 420, and the silicon-containing layer 440 disposed on inner surfaces of the trenches 430. The device 402 further includes an oxide layer 460 extending from the silicon-containing layer 440 at the bottom 432 of each trench 430, and a capping layer 480 disposed on the silicon-containing layer 440 and the oxide layer 460 at a top of each trench 430. Also, the airgaps 470 are disposed between and/or encapsulated by the silicon-containing layer 440, the oxide layer 460, and the capping layer 480.

A plurality of devices 402 may be produced, fabricated, manufactured, or otherwise made by the method 300. In other embodiments, other devices, not described or discussed herein, may also be produced, fabricated, manufactured, or otherwise made by the method 300. In one or more examples, the device 402 is, comprises, includes, consists of, or consists essentially of, one or more transistors. In some examples, the device 402 (or the transistor) is a complementary metal-oxide-semiconductor (CMOS) transistor, a metal-oxide-semiconductor field-effect transistor (MOSFET), a gate-all-around (GAA) transistor, a fin field effect transistor (FinFET), complementary field effect transistor (CFET), other types of transistors, or any combination thereof.

Although FIG. 4F depicts a single device 402 with the airgap 470 on the workpiece 400, in practice, numerous amounts (e.g., up to millions) of the devices 402 with the airgaps 470 may be produced, fabricated, manufactured, or otherwise made on the workpiece 400 by the method 300. In addition, although FIGS. 4A-4F depict the metal-gate layer 420 deposited or disposed directly on or over the substrate 410, in practice one or more other layers and/or materials may be between the metal-gate layer 420 and the substrate 410 depending on the specific architecture of the overall microelectronic device.

Prior to operation 310, the workpiece 400 containing the metal-gate layer 420 disposed on the substrate 410 may be exposed to one or more processes or operations in order to form the trenches 430. For example, the trenches 430 may be produced, fabricated, or otherwise formed in the metal-gate layer 420 by one or more etching process, such as one or more wet etch processes, one or more dry etch processes, of any combination thereof.

In one or more embodiments, each of the trenches 430 may have an aspect ratio in a range from about 4, about 5, about 6, about 7, about 8, about 9, about 10, about 12, or about 14 to about 15, about 16, about 18, about 20, about 22, about 25, about 28, about 30, about 35, about 40, about 45, about 50, about 60, about 75, about 80, about 100, or greater. For example, each of the trenches 430 may have an aspect ratio in a range from about 4 to about 100, about 6 to about 100, about 6 to about 80, about 6 to about 50, about 6 to about 40, about 6 to about 30, about 6 to about 20, about 6 to about 15, about 6 to about 12, about 6 to about 10, about 6 to about 8, about 8 to about 100, about 8 to about 80, about 8 to about 50, about 8 to about 40, about 8 to about 30, about 8 to about 20, about 8 to about 15, about 8 to about 12, about 8 to about 10, about 10 to about 100, about 10 to about 80, about 10 to about 50, about 10 to about 40, about 10 to about 30, about 10 to about 20, about 10 to about 15, or about 10 to about 12. The aspect ratio is measured as a ratio of depth (or height) over width (or diameter) of the trench 430.

At operation 310, the silicon-containing layer 440 may be deposited, disposed, or otherwise formed on inner surfaces of trenches 430 formed in the metal-gate layer 420 disposed on or over the substrate 410. Each of the trenches 430 may have a bottom 432, a top 434, and sidewalls 436 therebetween, which are all part of the inner surfaces of the trenches 430. In some examples, the top 434 of each trench 430 may have a width or a diameter greater than the bottom 432 of each trench 430 (as depicted in FIGS. 4A-4F). In other examples, not shown, the top 434 of each trench 430 may have a width or a diameter equal to or substantially equal to the bottom 432 of each trench 430, such the sidewalls 436 are parallel or substantially parallel to each other.

The silicon-containing layer 440 may be or contain silicon nitride, silicon oxide, silicon oxynitride, or any combination thereof. In one or more examples, the silicon-containing layer 440 may be or contain silicon nitride. In some examples, the silicon-containing layer 440 consists completely of silicon nitride or consist essentially of silicon nitride. In other embodiments, the silicon-containing layer 440 may or contain one or more dielectric materials which can be selectively maintained without being removed or damaged when removing the carbon-containing layer 450 while exposing the silicon-containing layer 440 in a later fabrication process (e.g., operation 340). The silicon-containing layer 440 may be deposited or otherwise formed by one or more vapor deposition processes. Exemplary vapor deposition processes may be or include a thermal ALD process, a PE-ALD process, a thermal CVD process, a PE-CVD process, a PVD process, or any combination thereof.

In one or more embodiments, the silicon-containing layer 440 may have a thickness in a range from about 0.1 nm, about 0.5 nm, about 0.8 nm, about 1 nm, about 1.5 nm, about 2 nm, about 3 nm, or about 4 nm to about 5 nm, about 6 nm, about 7 nm, about 8 nm, about 9 nm, about 10 nm, about 12 nm, about 15 nm, about 18 nm, about 20 nm, about 30 nm, about 50 nm, or greater. For example, the silicon-containing layer 440 may have a thickness in a range from about 0.1 nm to about 50 nm, about 0.5 nm to about 50 nm, about 1 nm to about 50 nm, about 2 nm to about 50 nm, about 3 nm to about 50 nm, about 4 nm to about 50 nm, about 5 nm to about 50 nm, about 8 nm to about 50 nm, about 10 nm to about 50 nm, about 15 nm to about 50 nm, about 20 nm to about 50 nm, about 0.5 nm to about 10 nm, about 1 nm to about 10 nm, about 2 nm to about 10 nm, about 3 nm to about 10 nm, about 4 nm to about 10 nm, about 5 nm to about 10 nm, about 8 nm to about 10 nm, about 0.5 nm to about 5 nm, about 1 nm to about 5 nm, about 2 nm to about 5 nm, about 3 nm to about 5 nm, about 4 nm to about 5 nm, about 0.5 nm to about 3 nm, about 1 nm to about 3 nm, or about 2 nm to about 3 nm.

At operation 320, the carbon-containing layer 450 may be deposited, disposed, or otherwise formed on the silicon-containing layer 440 which is disposed on the sidewalls 436 and the bottoms 432 of the trenches 430 during a first deposition process. In one or more examples, the carbon-containing layer 450 comprises, contains, includes, consists, or consists essential of amorphous carbon. In some examples, the carbon-containing layer 450 consists essential of amorphous carbon. In other embodiments, the carbon-containing layer 450 may or contain one or more sacrificial materials which can be selectively removed from the underlying layer, such as the silicon-containing layer 440, without removing or damaging the underlying layer.

The carbon-containing layer 450 may be deposited or otherwise formed by one or more vapor deposition processes. Exemplary vapor deposition processes may be or include a MLD process, a thermal ALD process, a PE-ALD process, a thermal CVD process, a PE-CVD process, an F-CVD process, or any combination thereof. In one or more examples, the carbon-containing layer 450 is deposited by an MLD process on the silicon-containing layer 440 throughout and within the trenches 430 during the first deposition process. In other examples, the carbon-containing layer 450 is deposited by a PE-ALD process on the silicon-containing layer 440 throughout and within the trenches 430 during the first deposition process.

The carbon-containing layer 450 may have a density in a range from about 0 g/cm³, about 0.0001 g/cm³, about 0.001 g/cm³, about 0.01 g/cm³, about 0.1 g/cm³, about 0.2 g/cm³, about 0.3 g/cm³, about 0.4 g/cm³, about 0.5 g/cm³, about 0.6 g/cm³, about 0.7 g/cm³, about 0.8 g/cm³, about 0.9 g/cm³, or about 1 g/cm³ to about 1.1 g/cm³, about 1.2 g/cm³, about 1.3 g/cm³, about 1.4 g/cm³, about 1.5 g/cm³, about 1.6 g/cm³, about 1.7 g/cm³, about 1.8 g/cm³, about 1.9 g/cm³, about 2 g/cm³, or greater. For example, the carbon-containing layer 450 may have a density in a range from about 0.01 g/cm³ to about 2 g/cm³, about 0.1 g/cm³ to about 2 g/cm³, about 0.2 g/cm³ to about 2 g/cm³, about 0.5 g/cm³ to about 2 g/cm³, about 0.8 g/cm³ to about 2 g/cm³, about 1 g/cm³ to about 2 g/cm³, about 1.2 g/cm³ to about 2 g/cm³, about 1.5 g/cm³ to about 2 g/cm³, about 1.6 g/cm³ to about 2 g/cm³, about 1.8 g/cm³ to about 2 g/cm³, about 0.01 g/cm³ to about 1.5 g/cm³, about 0.1 g/cm³ to about 1.5 g/cm³, about 0.2 g/cm³ to about 1.5 g/cm³, about 0.5 g/cm³ to about 1.5 g/cm³, about 0.8 g/cm³ to about 1.5 g/cm³, about 1 g/cm³ to about 1.5 g/cm³, about 1.2 g/cm³ to about 1.5 g/cm³, about 1.3 g/cm³ to about 1.5 g/cm³, about 0.01 g/cm³ to about 1 g/cm³, about 0.1 g/cm³ to about 1 g/cm³, about 0.2 g/cm³ to about 1 g/cm³, about 0.5 g/cm³ to about 1 g/cm³, about 0.8 g/cm³ to about 1 g/cm³, about 0.9 g/cm³ to about 1 g/cm³, about 0.01 g/cm³ to about 0.8 g/cm³, about 0.1 g/cm³ to about 0.8 g/cm³, about 0.2 g/cm³ to about 0.8 g/cm³, about 0.5 g/cm³ to about 0.8 g/cm³, or about 0.6 g/cm³ to about 0.8 g/cm³.

At operation 330, the first deposition process may be ceased or otherwise stopped to leave a temporary gap 452 within each of the trenches 430. The temporary gap 452 is a permanent fixture until the interior is later filled with one or more materials (e.g., the oxide layer 460).

At operation 340, the method 300 further includes exposing the carbon-containing layer 450 to a first treatment process to etch or otherwise remove the carbon-containing layer 450 from the bottom 432 of each temporary gap 452. The first treatment process reveals or otherwise exposes the silicon-containing layer 440 at the bottom 432 of each temporary gaps 452, as depicted in FIG. 4C. The first treatment process may be one or more dry etch processes, such as a thermal dry etch process or a plasma dry etch process.

At operation 350, the oxide layer 460 may be deposited, disposed, or otherwise formed into each of the temporary gaps 452 during a second deposition process. In one or more examples, the oxide layer 460 may be deposited, disposed, or otherwise formed into each of the temporary gaps 452 to completely fill or substantially fill the temporary gap 452 at operation 350. The oxide layer 460 may extend between the silicon-containing layer 440 at the bottom 432 of each trench 430 to the capping layer 480 in each of the trenches 430. The oxide layer 460 may be or include one or more of silicon oxide, silicon oxynitride, aluminum oxide, titanium oxide, other metal oxides, silicates thereof, or any combination thereof. In one or more examples, the oxide layer 460 comprises, consists, or consists essential of silicon oxide.

In some embodiments, the second deposition process may be a bottom-up deposition process, such as a gap fill process. The oxide layer 460 may be may be deposited, disposed, or otherwise formed by one or more deposition processes. Exemplary deposition processes for depositing the oxide layer 460 may be or include an F-CVD process, a thermal ALD process, a PE-ALD process, a thermal CVD process, a PE-CVD process, or any combination thereof.

In one or more examples, the oxide layer 460 is deposited by forming a flowable dielectric layer in the trenches 430, and then solidifying the oxide layer 460, such as by a thermal or annealing process, to produce the oxide layer 460. For example, the flowable dielectric layer may be formed during a vapor deposition process from one, two, or more silicon precursors and one or more oxygen precursors (e.g., oxygenating agents). In one or more examples, the flowable dielectric layer may be formed during a vapor deposition process from a first silicon precursor, a second silicon precursor, and an oxygen precursor.

At operation 360, the carbon-containing layer 450 may be exposed to a second treatment process to etch or remove the carbon-containing layer 450 and form dielectric airgaps 470 between the silicon-containing layer 440 and the oxide layer 460. The carbon-containing layer 450 is exposed to one or more ashing processes, one or more dry linear removal processes, one or more UV radiation (e.g., light) processes, or any combination thereof during the second treatment process.

In one or more examples, the carbon-containing layer 450 is exposed to an ashing process during the second treatment process, where the ashing process includes exposing the carbon-containing layer 450 to one or more oxidizers in a thermal process or a plasma process. Exemplary oxidizers may be or include oxygen (O₂), atomic oxygen, ozone, nitrous oxide, water, plasmas thereof, or any combination thereof.

In other examples, the carbon-containing layer 450 is exposed to ultraviolet (UV) radiation (e.g., UV light) during the second treatment process. The UV radiation or light has a wavelength in a range from about 100 nm, about 120 nm, about 135 nm, about 150 nm, about 165 nm, about 180 nm, about 200 nm, about 220 nm, about 235 nm, about 250 nm, about 265 nm, about 280 nm, about 300 nm, or greater. For examples, the UV radiation or light has a wavelength in a range from about 100 nm to about 300 nm, about 150 nm to about 300 nm, about 150 nm to about 275 nm, about 150 nm to about 250 nm, about 150 nm to about 225 nm, about 150 nm to about 200 nm, about 150 nm to about 175 nm, about 180 nm to about 300 nm, about 180 nm to about 275 nm, about 180 nm to about 250 nm, about 180 nm to about 225 nm, about 180 nm to about 200 nm, about 200 nm to about 300 nm, about 200 nm to about 275 nm, about 200 nm to about 250 nm, or about 200 nm to about 225 nm.

In some embodiments, the carbon-containing layer 450 is heated to a temperature in a range from about 100° C., about 150° C., about 200° C., about 225° C., about 250° C., about 275° C., about 300° C., about 350° C., about 400° C., about 450° C., about 500° C., about 550° C., about 600° C., about 650° C., about 700° C., about 750° C., or greater during the second treatment process (e.g., a thermal treatment). For example, the carbon-containing layer 450 is heated to a temperature in a range from about 150° C. to about 750° C., about 150° C. to about 700° C., about 150° C. to about 650° C., about 150° C. to about 600° C., about 150° C. to about 550° C., about 150° C. to about 500° C., about 150° C. to about 450° C., about 150° C. to about 400° C., about 150° C. to about 350° C., about 150° C. to about 300° C., about 150° C. to about 250° C., about 150° C. to about 200° C., about 250° C. to about 750° C., about 250° C. to about 700° C., about 250° C. to about 650° C., about 250° C. to about 600° C., about 250° C. to about 550° C., about 250° C. to about 500° C., about 250° C. to about 450° C., about 250° C. to about 400° C., about 250° C. to about 350° C., about 250° C. to about 300° C., about 350° C. to about 750° C., about 350° C. to about 700° C., about 350° C. to about 650° C., about 350° C. to about 600° C., about 350° C. to about 550° C., about 350° C. to about 500° C., about 350° C. to about 450° C., about 350° C. to about 400° C. during the second treatment process (e.g., a thermal treatment).

At operation 370, the capping layer 480 may be deposited, disposed, or otherwise formed over the airgaps 470, the silicon-containing layer 440, and the oxide layer 460 while producing, fabricating, or otherwise forming a device 402. Each of the airgaps 470 is an airgap disposed between and/or encapsulated by the silicon-containing layer 440, the oxide layer 460, and the capping layer 480.

The capping layer 480 may be or contain silicon oxide, silicon nitride, silicon oxynitride, a metal oxide, or any combination thereof. The capping layer 480 may be may be deposited, disposed, or otherwise formed by one or more deposition processes. Exemplary deposition processes for depositing the capping layer 480 may be or include a thermal ALD process, a PE-ALD process, a thermal CVD process, a PE-CVD process, or any combination thereof.

In one or more embodiments, the capping layer 480 may have a thickness in a range from about 1 nm, about 5 nm, about 8 nm, about 10 nm, about 12 nm, about 15 nm, about 18 nm, or about 20 nm to about 25 nm, about 30 nm, about 35 nm, about 40 nm, about 45 nm, about 50 nm, about 60 nm, about 70 nm, about 80 nm, about 90 nm, about 100 nm, or greater. For example, the capping layer 480 may have a thickness in a range from about 1 nm to about 100 nm, about 5 nm to about 100 nm, about 5 nm to about 80 nm, about 5 nm to about 60 nm, about 5 nm to about 50 nm, about 5 nm to about 40 nm, about 5 nm to about 30 nm, about 5 nm to about 25 nm, about 5 nm to about 20 nm, about 5 nm to about 15 nm, about 5 nm to about 10 nm, about 5 nm to about 8 nm, about 10 nm to about 100 nm, about 10 nm to about 80 nm, about 10 nm to about 60 nm, about 10 nm to about 50 nm, about 10 nm to about 40 nm, about 10 nm to about 30 nm, about 10 nm to about 25 nm, about 10 nm to about 20 nm, about 10 nm to about 15 nm, about 10 nm to about 12 nm, about 20 nm to about 100 nm, about 20 nm to about 80 nm, about 20 nm to about 60 nm, about 20 nm to about 50 nm, about 20 nm to about 40 nm, about 20 nm to about 30 nm, or about 20 nm to about 25 nm.

After operation 370, one or more additional processes or operations may be performed on the workpiece 400. In one or more examples, the capping layer 480 may be exposed to one or more polishing processes, such as a chemical mechanical polishing (CMP) process, to reduce a thickness of the capping layer 480.

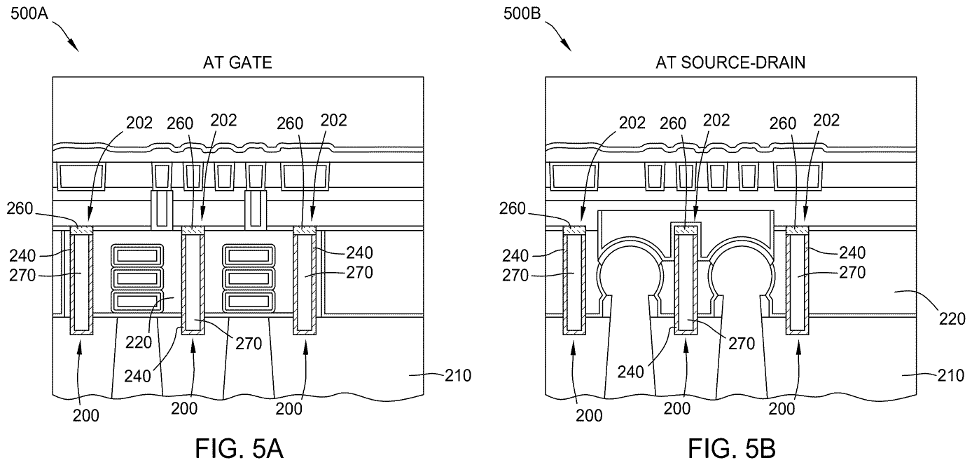

FIGS. 5A-5B depict cross-sectional views of portions a microelectronic device 500A and 500B (collectively 500), such as a metal gate structure, containing gate cut airgaps, such as a plurality of devices 202 depicted in FIG. 2D, according to one or more embodiments described and discussed herein. FIG. 5A depicts a view of a portion of the microelectronic device 500A near or at the gate and FIG. 5B depicts a view of a portion of the microelectronic device 500B near or at the source-drain.

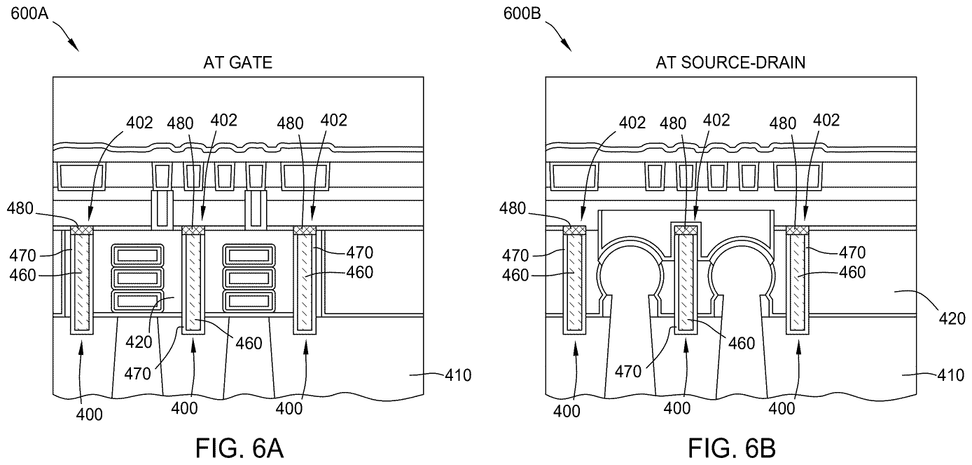

FIGS. 6A-6B depict cross-sectional views of portions a microelectronic device 600A and 600B (collectively 600), such as a metal gate structure, containing gate cut airgaps, such as a plurality of devices 402 depicted in FIG. 4F, according to one or more embodiments described and discussed herein. FIG. 6A depicts a view of a portion of the microelectronic device 600A near or at the gate and FIG. 6B depicts a view of a portion of the microelectronic device 600B near or at the source-drain.

In one or more embodiments, any one or more of the workpieces 200 and/or 400, the devices 202 and/or 402 and/or any one or more of the microelectronic devices 500 and/or 600 may be a complementary metal-oxide-semiconductor (CMOS) transistor, a metal-oxide-semiconductor field-effect transistor (MOSFET), a gate-all-around (GAA) transistor, a fin field effect transistor (FinFET), complementary field effect transistor (CFET), other types of transistors, or any combination thereof.

Most traditional chemical vapor deposition (CVD) chambers or atomic layer deposition (ALD) chambers may be used as the processing chamber suitable for performing the vapor deposition processes described and discussed herein. An example of a tool or system that may benefit from the vapor deposition processes described and discussed herein is the Centura® system or Endura® system with an iSprint™ ALD/CVD SSW chamber, commercially available from Applied Materials, Inc.

Embodiments of the present disclosure further relate to any one or more of the following Clauses 1-55:

Clause 1. A method for preparing a device with an airgap, comprising: depositing a silicon-containing layer on inner surfaces of trenches formed in a metal-gate layer disposed on a substrate, wherein each of the trenches has a top and a bottom; depositing a carbon-containing layer on the silicon-containing layer in the trenches during a bottom-up deposition process, wherein the carbon-containing layer is deposited to fill at least a lower half of the trenches from the bottom; ceasing the bottom-up deposition process to leave a temporary gap within each trench at the top; depositing a low-k dielectric layer into the temporary gap; and exposing at least the carbon-containing layer to a treatment process to remove the carbon-containing layer and form the airgap between the silicon-containing layer and the low-k dielectric layer.

Clause 2. The method according to Clause 1, wherein depositing the low-k dielectric layer into the temporary gap further comprises depositing the low-k dielectric layer on the carbon-containing layer and the silicon-containing layer to completely fill or substantially fill the temporary gap.

Clause 3. The method according to Clause 1 or 2, wherein the silicon-containing layer comprises silicon nitride, silicon oxide, silicon oxynitride, or any combination thereof.

Clause 4. The method according to any one of Clauses 1-3, wherein the silicon-containing layer consists or consists essentially of silicon nitride.

Clause 5. The method according to any one of Clauses 1-4, wherein the silicon-containing layer is deposited by an atomic layer deposition (ALD) process.

Clause 6. The method according to any one of Clauses 1-5, wherein the silicon-containing layer has a thickness in a range from about 0.5 nm to about 10 nm.

Clause 7. The method according to any one of Clauses 1-6, wherein the bottom-up deposition process is a molecular layer deposition (MLD) process or a plasma-enhanced chemical vapor deposition (PE-CVD) process.

Clause 8. The method according to any one of Clauses 1-7, wherein the temporary gap occupies less than an upper half of the trenches at the top after the bottom-up deposition process.

Clause 9. The method according to any one of Clauses 1-8, wherein the carbon-containing layer comprises, consists, or consists essential of amorphous carbon.

Clause 10. The method according to any one of Clauses 1-9, wherein the carbon-containing layer consists essential of amorphous carbon.

Clause 11. The method according to any one of Clauses 1-10, wherein the carbon-containing layer has a density in a range from about 0.01 g/cm³ to about 2 g/cm³.

Clause 12. The method according to any one of Clauses 1-11, wherein the carbon-containing layer is deposited by a MLD process during the bottom-up deposition process.

Clause 13. The method according to any one of Clauses 1-12, wherein the low-k dielectric layer comprises silicon, carbon, and oxygen.

Clause 14. The method according to any one of Clauses 1-13, wherein the low-k dielectric layer is deposited by forming a flowable dielectric layer in the trenches, and then solidifying the low-k dielectric layer to produce the low-k dielectric layer.

Clause 15. The method according to any one of Clauses 1-14, wherein the flowable dielectric layer is formed during a vapor deposition process from a first silicon carbon precursor, a second silicon carbon precursor, and an oxygen precursor.

Clause 16. The method according to any one of Clauses 1-15, wherein the low-k dielectric layer has a dielectric constant in a range from about 2.2 to about 3.0.

Clause 17. The method according to any one of Clauses 1-16, wherein the low-k dielectric layer has a thickness in a range from about 10 nm to about 50 nm.

Clause 18. The method according to any one of Clauses 1-17, further comprising exposing the low-k dielectric layer to a chemical mechanical polishing (CMP) process to reduce a thickness of the low-k dielectric layer.

Clause 19. The method according to any one of Clauses 1-18, wherein each of the trenches has an aspect ratio from about 6 to about 50.

Clause 20. The method according to any one of Clauses 1-19, wherein each of the trenches has an aspect ratio from about 10 to about 15.

Clause 21. The method according to any one of Clauses 1-20, wherein the top has a width or a diameter greater than the bottom.

Clause 22. The method according to any one of Clauses 1-21, wherein each of the airgaps is an airgap encapsulated by the silicon-containing layer and the low-k dielectric layer.

Clause 23. The method according to any one of Clauses 1-22, wherein the carbon-containing layer is exposed to ultraviolet radiation during the treatment process.

Clause 24. The method according to any one of Clauses 1-23, wherein the ultraviolet radiation has a wavelength in a range from about 150 nm to about 250 nm.

Clause 25. A method for preparing a device with an airgap, comprising: depositing a silicon-containing layer on inner surfaces of trenches formed in a metal-gate layer disposed on a substrate, wherein the inner surfaces of trenches for each of the trenches comprise sidewalls and a bottom; depositing a carbon-containing layer on the silicon-containing layer which is disposed on the sidewalls and the bottoms of the trenches during a first deposition process; ceasing the first deposition process to leave a temporary gap within each trench; removing the carbon-containing layer from the bottom of each temporary gap while exposing the silicon-containing layer at the bottom of each temporary gap; depositing an oxide layer into each temporary gap during a second deposition process to fill the temporary gap; exposing the carbon-containing layer to a treatment process to remove the carbon-containing layer and form airgaps between the silicon-containing layer and the oxide layer; and depositing a capping layer over the airgaps, the silicon-containing layer, and the oxide layer.

Clause 26. The method according to Clause 25, wherein the silicon-containing layer comprises silicon nitride, silicon oxide, silicon oxynitride, or any combination thereof.

Clause 27. The method according to Clause 25 or 26, wherein the silicon-containing layer consists or consists essentially of silicon nitride.

Clause 28. The method according to any one of Clauses 25-27, wherein the first deposition process is a MLD process or a plasma-enhanced atomic layer deposition (PE-ALD) process.

Clause 29. The method according to any one of Clauses 25-28, wherein the carbon-containing layer comprises, consists, or consists essential of amorphous carbon.

Clause 30. The method according to any one of Clauses 25-29, wherein the carbon-containing layer consists essential of amorphous carbon.

Clause 31. The method according to any one of Clauses 25-30, wherein the carbon-containing layer has a density in a range from about 0.01 g/cm³ to about 2 g/cm³.

Clause 32. The method according to any one of Clauses 25-31, wherein the oxide layer comprises, consists, or consists essential of silicon oxide.

Clause 33. The method according to any one of Clauses 25-32, wherein the oxide layer extends between the silicon-containing layer at the bottom of each trench to the capping layer in each trench.

Clause 34. The method according to any one of Clauses 25-33, wherein the second deposition process is a bottom-up deposition process, and wherein the second deposition process is a chemical vapor deposition (CVD) process or an atomic layer deposition (ALD) process.

Clause 35. The method according to any one of Clauses 25-34, wherein the carbon-containing layer is exposed to an ultraviolet radiation process, an ashing process, or a dry linear removal process during the treatment process.

Clause 36. The method according to any one of Clauses 25-35, wherein the carbon-containing layer is exposed to the ultraviolet radiation during the treatment process, and wherein the ultraviolet radiation has a wavelength in a range from about 150 nm to about 250 nm.

Clause 37. The method according to any one of Clauses 25-36, wherein the carbon-containing layer is exposed to the ashing process during the treatment process, and wherein the ashing process comprises exposing the carbon-containing layer to one or more oxidizers in a thermal process or a plasma process.

Clause 38. The method according to any one of Clauses 25-37, wherein each of the airgaps is an airgap encapsulated by the silicon-containing layer, the oxide layer, and the capping layer.

Clause 39. The method according to any one of Clauses 25-38, wherein the capping layer comprises silicon oxide, silicon nitride, silicon oxynitride, a metal oxide, or any combination thereof.

Clause 40. The method according to any one of Clauses 25-39, wherein the capping layer is deposited by a chemical vapor deposition (CVD) process.

Clause 41. The method according to any one of Clauses 25-40, wherein the capping layer has a thickness in a range from about 10 nm to about 50 nm.

Clause 42. The method according to any one of Clauses 25-41, further comprising exposing the capping layer to a chemical mechanical polishing (CMP) process to reduce a thickness of capping layer.

Clause 43. The method according to any one of Clauses 25-42, wherein the silicon-containing layer is deposited by an atomic layer deposition (ALD) process.

Clause 44. The method according to any one of Clauses 25-43, wherein the silicon-containing layer has a thickness in a range from about 0.5 nm to about 10 nm.

Clause 45. The method according to any one of Clauses 25-44, wherein each of the trenches has an aspect ratio from about 6 to about 50.

Clause 46. The method according to any one of Clauses 25-45, wherein each of the trenches has a top having a width or diameter greater than a bottom.

Clause 47. A device produced, fabricated, manufactured, or otherwise made by any one of the methods according to any one of Clauses 1-46.

Clause 48. The device according to Clause 47, wherein the device is or comprises a transistor.

Clause 49. The device according to Clause 47 or 48, wherein the transistor is a complementary metal-oxide-semiconductor (CMOS) transistor, a metal-oxide-semiconductor field-effect transistor (MOSFET), a gate-all-around (GAA) transistor, a fin field effect transistor (FinFET), complementary field effect transistor (CFET), or any combination thereof.

Clause 50. A device, comprising: a metal-gate layer disposed on or over a substrate; trenches formed within the metal-gate layer; a silicon-containing layer disposed on inner surfaces of the trenches; and a low-k dielectric layer disposed over the silicon-containing layer and at least partially within each of the trenches, wherein the airgap is disposed between and/or encapsulated by the silicon-containing layer and the low-k dielectric layer in each of the trenches.

Clause 51. A device, comprising: a metal-gate layer disposed on or over a substrate; trenches formed within the metal-gate layer; a silicon-containing layer disposed on inner surfaces of the trenches; an oxide layer extending from the silicon-containing layer at the bottom of each trench; and a capping layer disposed on the silicon-containing layer and the oxide layer at a top of each trench, wherein airgaps are disposed between and/or encapsulated by the silicon-containing layer, the oxide layer, and the capping layer.

Clause 52. The device according to Clause 50 or 51, wherein the device is or comprises a transistor.

Clause 53. The device according to any one of Clauses 50-52, wherein the transistor is a complementary metal-oxide-semiconductor (CMOS) transistor, a metal-oxide-semiconductor field-effect transistor (MOSFET), a gate-all-around (GAA) transistor, a fin field effect transistor (FinFET), complementary field effect transistor (CFET), or any combination thereof.

Clause 54. The device according to any one of Clauses 50-53, wherein the silicon-containing layer comprises silicon nitride, silicon oxide, silicon oxynitride, or any combination thereof.

Clause 55. The device according to any one of Clauses 50-54, wherein the silicon-containing layer consists or consists essentially of silicon nitride.

While the foregoing is directed to embodiments of the disclosure, other and further embodiments may be devised without departing from the basic scope thereof, and the scope thereof is determined by the claims that follow. All documents described herein are incorporated by reference herein, including any priority documents and/or testing procedures to the extent they are not inconsistent with this text. As is apparent from the foregoing general description and the specific embodiments, while forms of the present disclosure have been illustrated and described, various modifications may be made without departing from the spirit and scope of the present disclosure.

Accordingly, it is not intended that the present disclosure be limited thereby. Likewise, the term “comprising” is considered synonymous with the term “including” for purposes of United States law. Likewise, whenever a composition, an element, or a group of elements is preceded with the transitional phrase “comprising”, it is understood that the same composition or group of elements with transitional phrases “consisting essentially of”, “consisting of”, “selected from the group of consisting of”, or “is” preceding the recitation of the composition, element, or elements and vice versa, are contemplated. As used herein, the term “about” refers to a +/−10% variation from the nominal value. It is to be understood that such a variation may be included in any value provided herein.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated.

Certain lower limits, upper limits and ranges appear in one or more claims below.

What is claimed is:

1. A method for preparing a device with an airgap, comprising:
depositing a silicon-containing layer on inner surfaces of trenches formed in a metal-gate layer disposed on a substrate, wherein each of the trenches has a top and a bottom;
depositing a carbon-containing layer on the silicon-containing layer in the trenches during a bottom-up deposition process, wherein the carbon-containing layer is deposited to fill at least a lower half of the trenches from the bottom;
ceasing the bottom-up deposition process to leave a temporary gap within each trench at the top;
depositing a low-k dielectric layer into the temporary gap; and
exposing at least the carbon-containing layer to a treatment process to remove the carbon-containing layer and form the airgap between the silicon-containing layer and the low-k dielectric layer.

2. The method of claim 1, wherein depositing the low-k dielectric layer into the temporary gap further comprises depositing the low-k dielectric layer on the carbon-containing layer and the silicon-containing layer to completely fill or substantially fill the temporary gap.

3. The method of claim 1, wherein:
the silicon-containing layer comprises silicon nitride, silicon oxide, silicon oxynitride, or any combination thereof;
the silicon-containing layer has a thickness in a range from about 0.5 nm to about 10 nm; and
the silicon-containing layer is deposited by an atomic layer deposition (ALD) process.

4. The method of claim 1, wherein the bottom-up deposition process is a molecular layer deposition (MLD) process or a plasma-enhanced chemical vapor deposition (PE-CVD) process.

5. The method of claim 1, wherein the temporary gap occupies less than an upper half of the trenches at the top after the bottom-up deposition process.

6. The method of claim 1, wherein:
the carbon-containing layer comprises amorphous carbon;
the carbon-containing layer has a density in a range from about 0.01 g/cm³ to about 2 g/cm³; and
the carbon-containing layer is deposited by a molecular layer deposition (MLD) process during the bottom-up deposition process.

7. The method of claim 1, wherein:
the low-k dielectric layer comprises silicon, carbon, and oxygen;
the low-k dielectric layer is deposited by forming a flowable dielectric layer in the trenches, and then solidifying the low-k dielectric layer to produce the low-k dielectric layer; and
the flowable dielectric layer is formed during a vapor deposition process from a first silicon carbon precursor, a second silicon carbon precursor, and an oxygen precursor.

8. The method of claim 1, wherein the low-k dielectric layer has a dielectric constant in a range from about 2.2 to about 3.0, and a thickness in a range from about 10 nm to about 50 nm.

9. The method of claim 1, wherein each of the trenches has an aspect ratio from about 6 to about 50, and wherein the top has a width or a diameter greater than the bottom.

10. The method of claim 1, wherein each of the airgaps is an airgap encapsulated by the silicon-containing layer and the low-k dielectric layer.

11. The method of claim 1, wherein the carbon-containing layer is exposed to ultraviolet radiation during the treatment process, and wherein the ultraviolet radiation has a wavelength in a range from about 150 nm to about 250 nm.

12. A method for preparing a device with an airgap, comprising:
depositing a silicon-containing layer on inner surfaces of trenches formed in a metal-gate layer disposed on a substrate, wherein the inner surfaces of trenches for each of the trenches comprise sidewalls and a bottom;
depositing a carbon-containing layer on the silicon-containing layer which is disposed on the sidewalls and the bottoms of the trenches during a first deposition process;
ceasing the first deposition process to leave a temporary gap within each trench;
removing the carbon-containing layer from the bottom of each temporary gap while exposing the silicon-containing layer at the bottom of each temporary gap;
depositing an oxide layer into each temporary gap during a second deposition process to fill the temporary gap;
exposing the carbon-containing layer to a treatment process to remove the carbon-containing layer and form airgaps between the silicon-containing layer and the oxide layer; and
depositing a capping layer over the airgaps, the silicon-containing layer, and the oxide layer.

13. The method of claim 12, wherein the first deposition process is a molecular layer deposition (MLD) process or a plasma-enhanced atomic layer deposition (PE-ALD) process, and wherein the carbon-containing layer comprises amorphous carbon and has a density in a range from about 0.01 g/cm³ to about 2 g/cm³.

14. The method of claim 12, wherein the oxide layer comprises silicon oxide, and wherein the oxide layer extends between the silicon-containing layer at the bottom of each trench to the capping layer in each trench.

15. The method of claim 12, wherein the second deposition process is a bottom-up deposition process, and wherein the second deposition process is a chemical vapor deposition (CVD) process or an atomic layer deposition (ALD) process.

16. The method of claim 12, wherein the carbon-containing layer is exposed to an ultraviolet radiation process, an ashing process, or a dry linear removal process during the treatment process.

17. The method of claim 12, wherein each of the airgaps is an airgap encapsulated by the silicon-containing layer, the oxide layer, and the capping layer.

18. The method of claim 12, wherein the capping layer is deposited by a chemical vapor deposition (CVD) process, and wherein the capping layer has a thickness in a range from about 10 nm to about 50 nm.

19. The method of claim 12, wherein each of the trenches has an aspect ratio from about 6 to about 50, and wherein each of the trenches has a top having a width or diameter greater than a bottom.

20. A device, comprising:
a metal-gate layer disposed on or over a substrate;
trenches formed within the metal-gate layer;
a silicon-containing layer disposed on inner surfaces of the trenches;
an oxide layer extending from the silicon-containing layer at the bottom of each trench; and
a capping layer disposed on the silicon-containing layer and the oxide layer at a top of each trench, wherein airgaps are disposed between and/or encapsulated by the silicon-containing layer, the oxide layer, and the capping layer.
